(19) United States
(12) Patent Application Publication
(10) Pub. No.: US 2026/0369534 A1
(43) Pub. Date: Nov. 19, 2026

(54) STRAP HOUSING STRUCTURE FOR DELIVERING AN RF POWER AND A SUBSTRATE PROCESSING APPARATUS HAVING THE SAME

(71) Applicant: ASM IP Holding B.V., Almere (NL)

(72) Inventors: Arun Thottappayil, Chandler, AZ (US); DongRak Jung, Hwaseong-si (KR); Euijin Hong, Hwaseong-si (KR)

(21) Appl. No.: 19/671,841

(22) Filed: May 8, 2026

Related U.S. Application Data
(60) Provisional application No. 63/804,736, filed on May 13, 2025.

(51) Int. Cl. H01J 37/32; H05K 5/02; H05K 5/15; H05K 9/00

(52) U.S. Cl. CPC H01J 37/32889; H01J 37/32183; H01J 37/3244; H05K 5/0209; H05K 5/15; H05K 9/0009

(57) ABSTRACT

In one embodiment of the present disclosure, a strap housing structure for delivering an RF power to a heating block of a reactor is described.

The strap housing structure according to one embodiment of the present disclosure comprises: a metal strap to deliver an RF power, being configured to be connected to a matching network via a first end and to an RF filter via a second end; a body with a body space to house the metal strap therein; a plurality of insulators configured to hold the metal strap in place within the body space; and a connection member configured to connect the body to the RF filter.

### CROSS-REFERENCE TO RELATED APPLICATIONS

This application claims priority to U.S. Provisional Patent Application Ser. No. 63/804,736 filed May 13, 2025 titled STRAP HOUSING STRUCTURE FOR DELIVERING AN RF POWER AND A SUBSTRATE PROCESSING APPARATUS HAVING THE SAME, the disclosure of which is hereby incorporated by reference in its entirety.

### FIELD OF INVENTION

The present disclosure relates generally to a strap housing structure for delivering a radio frequency (RF) power and a substrate processing apparatus having the same. More particularly, the present disclosure relates to a strap housing structure for delivering an RF power to a heating block of a reactor of a substrate processing apparatus having the same.

### BACKGROUND OF THE DISCLOSURE

In a typical plasma process, an RF generator generates a power with a desired RF frequency, and this power is transmitted to a substrate processing chamber from a matching network via coaxial cables. A gas-phase reaction, such as chemical vapor deposition (CVD), plasma enhanced CVD (PECVD), atomic layer deposition (ALD), plasma enhanced atomic layer deposition (PEALD) and the like can be used for a variety of applications, including depositing and etching materials on a substrate surface. For example, a gas-phase reaction can be used to deposit and/or etch layers on a substrate to fabricate semiconductor devices, flat panel display devices, photovoltaic devices, microelectromechanical systems (MEMS), and the like.

A typical substrate processing chamber for the gas-phase reaction includes a reactor, one or more precursor gas sources fluidly coupled to the reactor, one or more carrier or purge gas sources fluidly coupled to the reactor, a gas distribution system to deliver a gas or gases (e.g., a precursor gas or gases and/or a carrier or purge gas or gases) to a surface of a substrate, and an exhaust source fluidly coupled to the reactor. The substrate processing chamber also typically includes a susceptor to hold a substrate in place during processing the substrate. The susceptor can be configured to move up and down to receive a substrate and/or can rotate during processing the substrate.

In a conventional substrate processing apparatus, one end of flexible coaxial cables is connected to a matching network and the other end of the flexible coaxial cables is connected an RF filter connected to a heating block. The coaxial cables are, however, easy to melt due to a hot chamber body, resulting in a damage to the cables, an arcing occurred between the cables and an RF filter, and an RF power loss. That issue becomes severe when a high RF power is delivered.

Therefore, the present disclosure presents a strap housing structure for delivering an RF power without an RF power loss when delivering a high RF power to the heating block from a matching network, and a substrate processing apparatus having the same.

### SUMMARY OF THE DISCLOSURE

This summary is provided to introduce a selection of concepts in a simplified form. These concepts are described in further detail in the detailed descriptions of exemplary embodiments of the disclosure below. This summary is not intended to identify key features or essential features of the claimed subject matter, nor is it intended to be used to limit the scope of the claimed subject matter.

In accordance with one exemplary embodiment, there may be provided a strap housing structure for delivering an RF power to a heating block of a reactor. The strap housing structure comprises: a metal strap to deliver an RF power, being configured to be connected to a matching network via a first end and to an RF filter via a second end; a body with a body space to house the metal strap therein; a plurality of insulators configured to hold the metal strap in place within the body space; and a connection member configured to connect the body to the RF filter.

In accordance with another exemplary embodiment, there may be provided a substrate processing apparatus. The substrate processing apparatus comprises: a reactor; a power generator to generate an RF power; a matching network connected to the power generator, being located above the reactor; a gas injector to supply a gas to a substrate from a gas source; a heating block disposed facing the gas injector, being configured to heat the substrate seated thereon in the reactor; an exhaust pump connected to the reactor to exhaust the reactor; an RF filter connected to the heating block, being located below the reactor; and a strap housing structure to deliver the RF power to the heating block from the power generator.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 shows a schematic diagram of a substrate processing apparatus in accordance with exemplary embodiments of the present disclosure.

FIG. 2 shows another schematic diagram of a substrate processing apparatus in accordance with exemplary embodiments of the present disclosure.

FIG. 3(a) shows conventional flexible coaxial cables connected to the matching network of the substrate processing apparatus; (b) shows a strap housing structure connected to the matching network of the substrate processing apparatus in accordance with exemplary embodiments of the present disclosure.

FIG. 4 shows two strap housing structures used in the substrate processing apparatus in accordance with exemplary embodiments of the present disclosure.

FIG. 5(a) shows a body and a connection member of a strap housing structure in accordance with exemplary embodiments of the present disclosure; (b) shows a partial enlarged view of the body of the strap housing structure in accordance with exemplary embodiments of the present disclosure; (c) shows a partial sectional enlarged view of the body of the strap housing structure in accordance with exemplary embodiments of the present disclosure.

FIG. 6 shows another partial sectional enlarged view of the body of the strap housing structure in accordance with exemplary embodiments of the present disclosure.

FIG. 7(a) shows an enlarged view of one of the plurality of insulators of the strap housing structure of the present disclosure; (b) shows a decomposition view of the strap housing structure of the substrate processing apparatus in accordance with exemplary embodiments of the present disclosure.

FIG. 8(a) shows other two strap housing structures used in the substrate processing apparatus in accordance with exemplary embodiments of the present disclosure; (b) shows another strap housing structure of the substrate processing apparatus in accordance with exemplary embodiments of the present disclosure; (c) shows another sectional view of the strap housing structure of the substrate processing apparatus in accordance with exemplary embodiments of the present disclosure.

FIG. 9(a)-(c) shows partial sectional enlarged views of the strap housing structure of the substrate processing apparatus in accordance with exemplary embodiments of the present disclosure.

FIG. 10(a) shows a sectional view of a connection member of the strap housing structure of the present disclosure; (b) shows a sectional perspective view of the connection member of the strap housing structure as shown in (a).

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers or a liquid crystal display panel in various shapes and sizes. Substrates may be made from semiconductor materials, including, for example, silicon, silicon germanium, silicon oxide, gallium arsenide, gallium nitride and silicon carbide, or non-crystalline materials, for example, a glass substrate for liquid crystal display.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

### Substrate Processing Apparatus

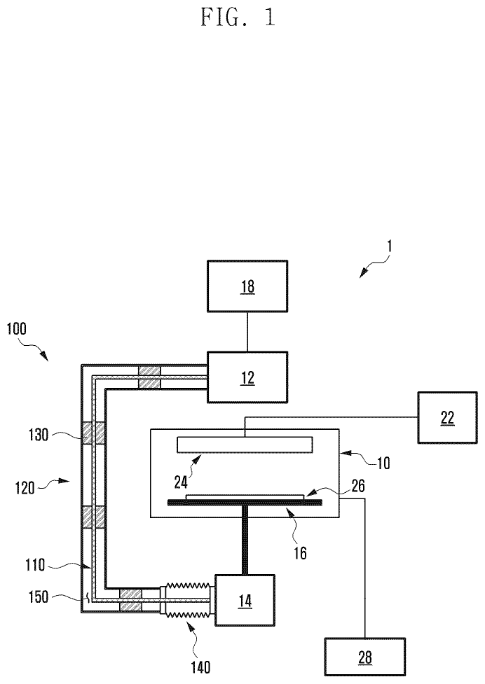

FIG. 1 shows a schematic diagram of a substrate processing apparatus 1 in accordance with exemplary embodiments of the present disclosure. The substrate processing apparatus 1 may comprise a reactor 10; a power generator 18 to generate an RF power; a matching network 12 connected to the power generator 18 and located above the reactor 10; a gas injector 24 to supply a gas to a substrate 26 from a gas source 22; a heating block 16 disposed facing the gas injector 24, being configured to heat the substrate 26 seated thereon; an exhaust pump 28 to exhaust the reactor 10; an RF filter 14 connected to the heating block 16 and located below the reactor 10; and a strap housing structure 100 to deliver the RF power to the heating block 16 from the power generator 18.

Referring to FIG. 1, the strap housing structure 100 may comprise a metal strap 110 to deliver the RF power, being configured to be connected to a matching network 12 via a first end and to the RF filter 14 via a second end; a body 120 with a body space 150 to house the metal strap 110 therein; a plurality of insulators 130 configured to hold the metal strap 110 in place within the body space 150; and a connection member 140 configured to connect the body 120 to the RF filter 14.

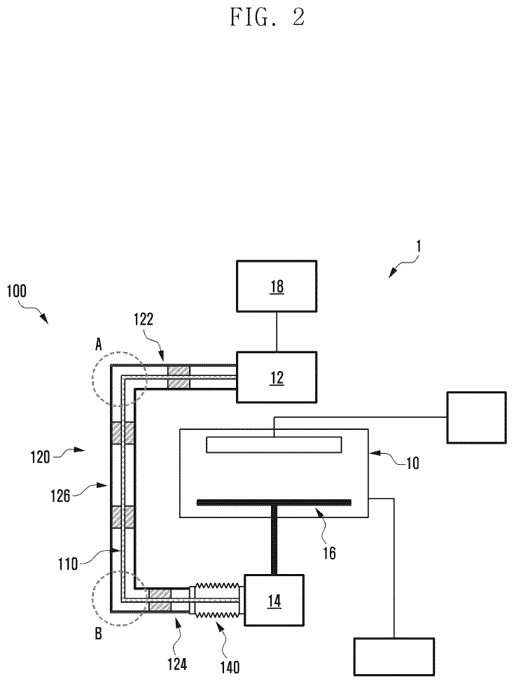

FIG. 2 shows another schematic diagram of a substrate processing apparatus 1 in accordance with exemplary embodiments of the present disclosure. Referring to FIG. 2, the body 120 of the strap housing structure 100 may comprise a first member 122 connected to the matching network 12, a second member 124 connected to the connection member 140, and a third member 126 connecting the first member 122 and the second member 124, and the first member 122 may be connected to the third member 126 at a first predetermined angle (A) and the second member 124 may be connected to the third member 126 at a second predetermined angle (B). The body 120 may comprise at least one of metal and plastic.

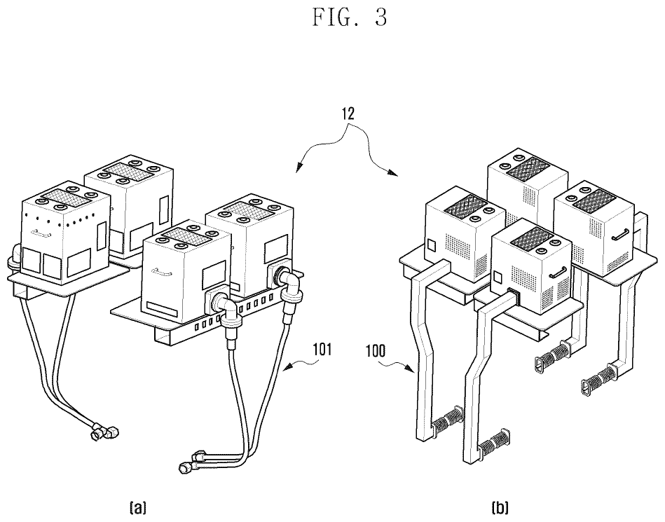

FIG. 3 panel (a) shows conventional flexible coaxial cables connected to the matching network 12 of the substrate processing apparatus 1. The conventional flexible coaxial cables 101 may be at risk of melting due to high temperature of a chamber body and/or high RF power, resulting in an RF power loss or an arcing between the coaxial cables and an RF filter.

FIG. 3 panel (b) shows a strap housing structure 100 connected to the matching network 12 of the substrate processing apparatus 1 in accordance with exemplary embodiments of the present disclosure. The strap housing structure 100 of the present disclosure may prevent the RF power loss or an arcing from occurring when a high RF power is delivered to the heating block from the matching network 12 or a high temperature process is carried out.

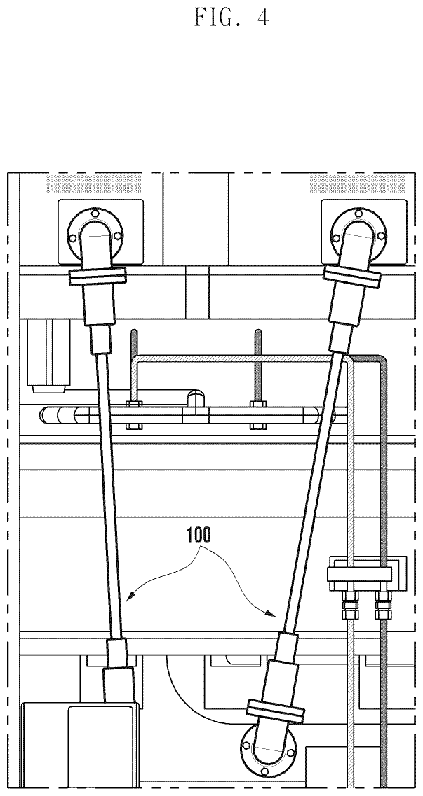

FIG. 4 shows two strap housing structures 100 used in the substrate processing apparatus 1 in accordance with exemplary embodiments of the present disclosure. Referring to FIG. 4 along with FIGS. 1 and 2, each of two strap housing structures 100 as shown in FIG. 4 may be embodied by either the strap housing structures 100 as shown in FIG. 1 or FIG. 2.

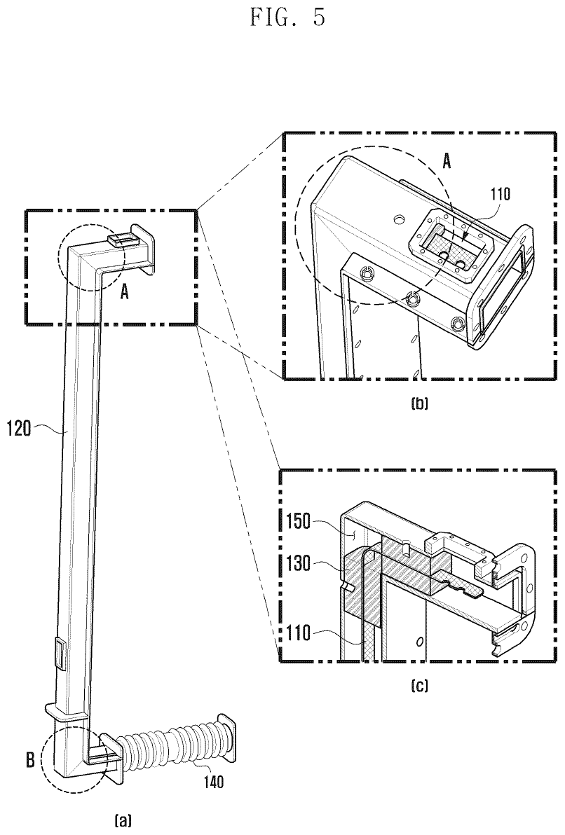

FIG. 5 panel (a) shows a body 120 and a connection member 140 of a strap housing structure 100 in accordance with exemplary embodiments of the present disclosure. The body 120 serves as the main housing unit for internal components. The connection member 140 may connect the body 120 to the RF filter 14 as shown in FIG. 1. As shown in FIG. 2 and FIG. 5 panel (a), the body 120 may comprise a first member 122 connected to the matching network 12, a second member 124 connected to the connection member 140, and a third member 126 connecting the first member 122 and the second member 124, wherein the first member 122 may be connected to the third member 126 at a first predetermined angle A and the second member 124 may be connected to the third member 126 at a second predetermined angle B.

FIG. 5 panel (b) shows a partial enlarged view of the body 120 of the strap housing structure 100 in accordance with exemplary embodiments of the present disclosure. FIG. 5 panel (b) may be an enlarged view of the first member 122 of FIG. 2 and the first member 122 may be connected to the third member 126 at a first predetermined angle A. The metal strap 110 may be positioned within the body 120 and may be spaced apart from the surrounding structure. The metal strap 110 may deliver a RF power from the power generator 18 via the matching network 12 to the heating block 16 via the RF filter 14.

FIG. 5 panel (c) shows a partial sectional enlarged view of the body 120 of the strap housing structure 100 in accordance with exemplary embodiments of the present disclosure. FIG. 5 panel (c) highlights the metal strap 110 and insulators 130. The metal strap 110 may be held in place within the body space 150 by the insulators 130. The insulators 130 support and electrically isolate the metal strap 110 using materials like plastic or ceramic. The insulators 130 may hold the metal strap 110 in place within the body space 150, resulting in the metal strap 110 spaced apart from the body 120.

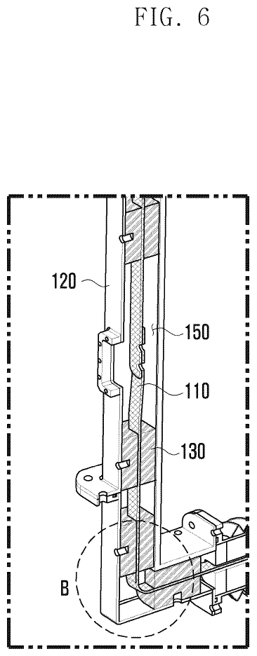

FIG. 6 shows another partial sectional enlarged view of the body 120 of the strap housing structure 100 in accordance with exemplary embodiments of the present disclosure. The metal strap 110 may be spaced apart from the body 120 within the body space 150 by the insulators 130 as shown in FIG. 5 panel (c). FIG. 6 may be an enlarged view of the second member 124 of FIG. 2 and the second member 124 may be connected to the third member 126 at a second predetermined angle B.

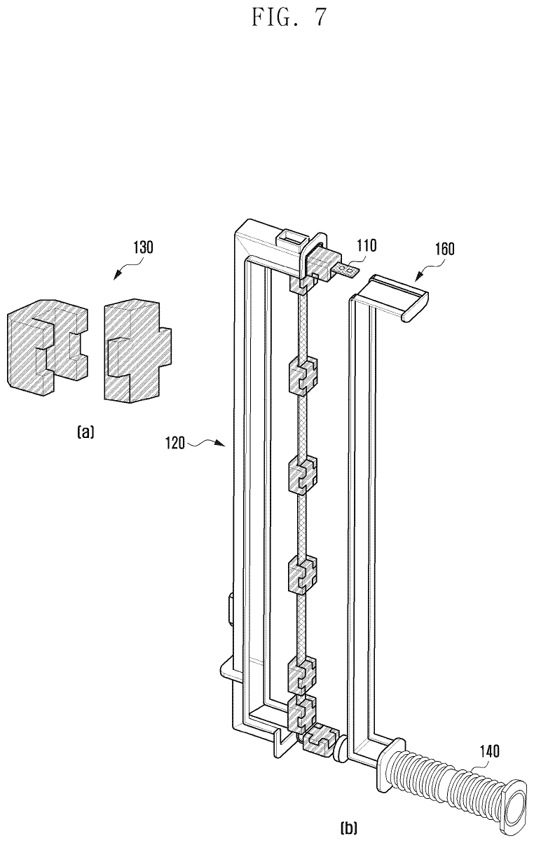

FIG. 7 panel (a) shows an enlarged view of one of the plurality of insulators 130 of the strap housing structure 100 of the present disclosure. Each of the plurality of insulators 130 may comprise at least one of plastic, ceramic, and the mixture thereof. The insulators 130 may be coupled tightly with a space, e.g., a slit, therebetween for the metal strap 110 to pass. The number of the insulators 130 holding the metal strap 110 may be two, but the number of the insulators 130 may not be limited thereto. For instance, a one-piece insulator with a through-slit penetrating the insulator may be used to hold the metal strap 110 in place. Or three or four pieces of the insulators 130 may be coupled to hold the metal strap 110 in place.

FIG. 7 panel (b) shows a decomposition view of the strap housing structure 100 of the substrate processing apparatus 1 in accordance with exemplary embodiments of the present disclosure. Each of the plurality of insulators 130 may comprise one or more components to hold the metal strap 110 in place within the body space 150. The strap housing structure 100 may further comprise an electromagnetic interference member 160 configured to cover the metal strap 110 to prevent an RF radiation leak therefrom. The electromagnetic interference member 160 may cover at least one side of the body 120. For instance, the electromagnetic interference member 160 may cover at least one side of the first member 122, one side of the second member 124, and one side of the third member 126 of the body 120 of FIG. 2.

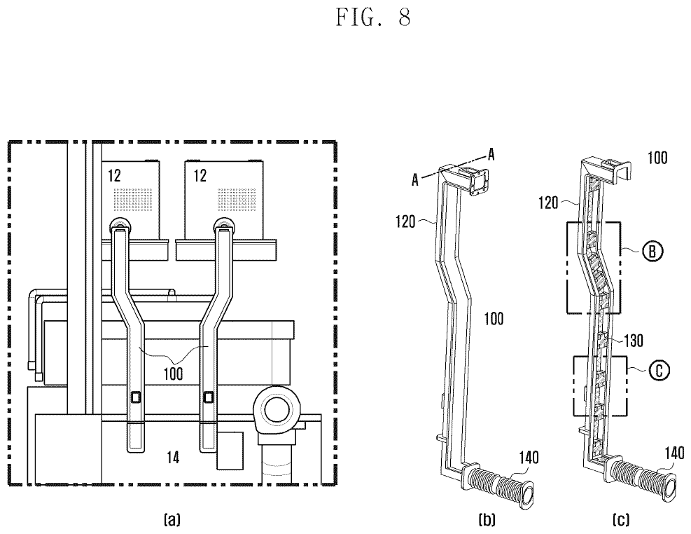

FIG. 8 panel (a) shows two strap housing structures 100 used in the substrate processing apparatus 1 in accordance with exemplary embodiments of the present disclosure. Each of the strap housing structure 100 features an angled design, which may be useful when the matching network 12 and the RF filter 14 are misaligned. As shown in FIG. 8 panel (a), the present disclosure may facilitate the body 120 to have various angled design to connect the matching network 12 and the RF filter 14 via the metal strap 110.

FIG. 8 panel (b) shows another strap housing structure 100 of the substrate processing apparatus 1 in accordance with exemplary embodiments of the present disclosure. This angled strap housing structure 100 also shows the body 120 and the connection member 140 as shown in FIG. 5 panel (a).

FIG. 8 panel (c) shows another sectional view of the strap housing structure 100 of the substrate processing apparatus 1 in accordance with exemplary embodiments of the present disclosure. This angled strap housing structure 100 also shows the body 120, the insulators 130, and the connection member 140 as shown in FIG. 5(a) and FIG. 6. The body 120 may comprise at least one angled portion B and one straight portion B depending on the degree of misalignment of the locations of the matching network 12 and the RF filter 14. In another embodiment, the number of angled portion and the straight portion may be two or more depending on the degree of misalignment of the locations of the matching network 12 and the RF filter 14.

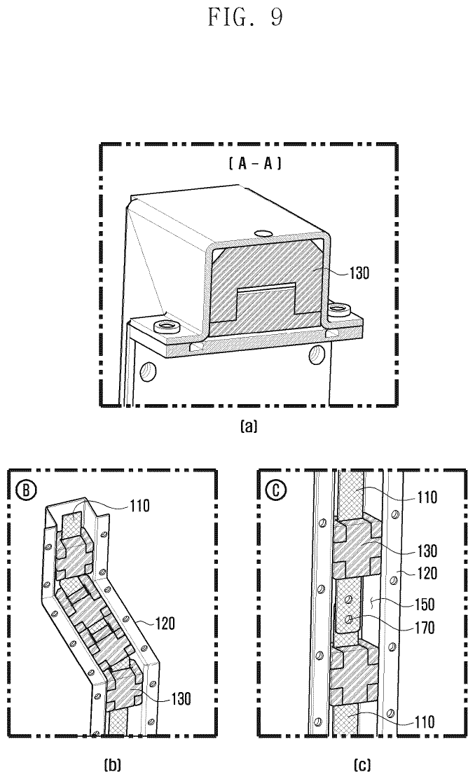

FIG. 9(a)-9(c) show partial sectional enlarged views of the strap housing structure 100 of the substrate processing apparatus 1 in accordance with exemplary embodiments of the present disclosure. FIG. 9 panel (a) shows a cross-section of the body 120 in FIG. 8 panel (b), along the section line A-A, to illustrate one of the insulators 130. FIG. 9 panel (b) shows a close-up view of section B of the body 120 in FIG. 8(c), highlighting the metal strap 110 and the insulators 130. FIG. 9 panel (b) may be an angled portion of the body 120. FIG. 9 panel (c) shows another close-up view of section C of body 120 in FIG. 8 panel (c), highlighting the metal strap 110, the insulators 130, and the body space 150. FIG. 9 panel (c) may be a straight portion of the body 120. As shown in FIGS. 8 and 9, the metal strap 110 may comprise a one body. In another embodiment, the metal strap 110 may comprise two or more bodies. As shown in FIG. 9 panel (c), multiple metal straps 110 may be connected by coupling measures 170, e.g., screws.

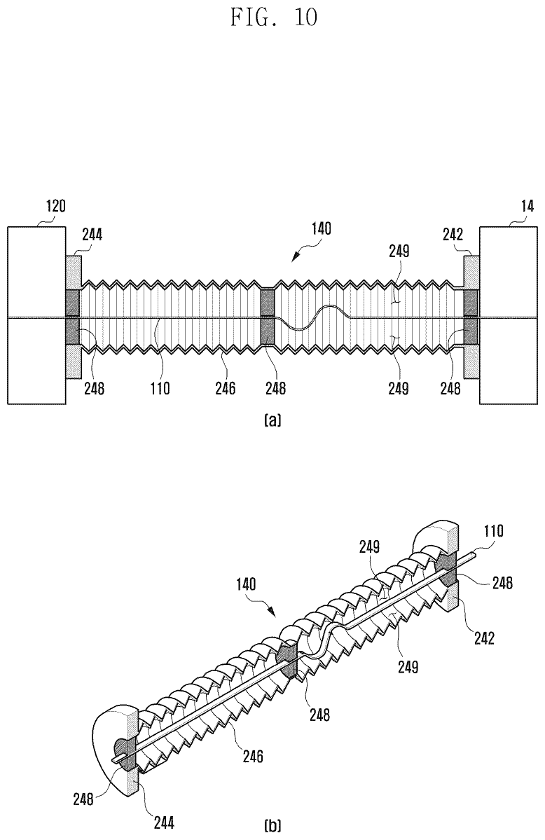

FIG. 10 panel (a) shows a sectional view of a connection member 140 of the strap housing structure 100 of the present disclosure. FIG. 10 panel (b) shows a sectional perspective view of the connection member 140 of the strap housing structure 100 as shown in FIG. 10 panel (a) of the present disclosure. The connection member 140 may comprise a moving end member 242 connected to the RF filter 14, a fixed end member 244 connected to the body 120, and a bellows 246 provided between the moving end member 242 and the fixed end member 244. Each of the moving end member 242, the fixed end member 244, and the bellows 246 may comprise a support member 248 for supporting the metal strap 110 in the bellows 246, wherein the metal strap 110 may be spaced apart from the bellows 246 within a bellows space 249 thereof. The support member 248 may comprise an insulator such as Teflon, plastic, or a ceramic.

Referring to FIG. 5(a) to FIG. 10(b), the metal strap 110 to deliver the RF power may be securely and stably received in the strap housing structure 100 to be connected between the matching network 12 and the RF filter 14, and thus, the strap housing structure 100 of the present disclosure may be operated without facing the risk of melting and/or a RF power loss.

While the present invention has been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

The above-described arrangements of a strap housing structure for delivering an RF power and a substrate processing apparatus having the same in a substrate process are merely illustrative of applications of the principles of this invention and many other embodiments and modifications may be made without departing from the spirit and scope of the invention as defined in the claims. The scope of the present invention should, therefore, be determined not with reference to the above description, but instead should be determined with reference to the appended claims along with their full scope of equivalents.

1. A strap housing structure for delivering a radio frequency (RF) power to a heating block of a reactor, the strap housing structure comprising:
a metal strap to deliver an RF power, being configured to be connected to a matching network via a first end and to an RF filter via a second end;
a body with a body space to house the metal strap therein;
a plurality of insulators configured to hold the metal strap in place within the body space; and
a connection member configured to connect the body to the RF filter.

2. The strap housing structure of claim 1, wherein the matching network is located above the reactor, and the RF filter is connected to the heating block below the reactor.

3. The strap housing structure of claim 1, wherein each of the plurality of insulators comprises one or more components to hold the metal strap in place within the body space.

4. The strap housing structure of claim 3, wherein the metal strap is spaced apart from the body within the body space.

5. The strap housing structure of claim 1, wherein each of the plurality of insulators comprises at least one of plastic, ceramic, and the mixture thereof.

6. The strap housing structure of claim 1, wherein the connection member comprises a moving end member connected to the RF filter, a fixed end member connected to the body, and a bellows provided between the moving end member and the fixed end member.

7. The strap housing structure of claim 6, wherein each of the moving end member, the fixed end member, and the bellows comprises a support member for supporting the metal strap in the bellows, wherein the metal strap is spaced apart from the bellows within a bellows space thereof.

8. The strap housing structure of claim 7, wherein the support member comprises an insulator.

9. The strap housing structure of claim 1, wherein the body comprises a first member connected to the matching network, a second member connected to the connection member, and a third member connecting the first member and the second member, wherein the first member is connected to the third member at a first predetermined angle and the second member is connected to the third member at a second predetermined angle.

10. The strap housing structure of claim 1, wherein the body comprises at least one of metal and plastic.

11. The strap housing structure of claim 1, further comprising an electromagnetic interference member configured to cover the metal strap to prevent an RF radiation leak therefrom.

12. A substrate processing apparatus 1 comprising:
a reactor;
a power generator to generate a radio frequency (RF) power;
a matching network connected to the power generator, being located above the reactor;
a gas injector to supply a gas to a substrate from a gas source;
a heating block disposed facing the gas injector, being configured to heat the substrate seated thereon in the reactor;
an exhaust pump connected to the reactor to exhaust the reactor;
an RF filter connected to the heating block, being located below the reactor; and
a strap housing structure to deliver the RF power to the heating block from the power generator.

13. The substrate processing apparatus of claim 12, wherein the strap housing structure comprises a metal strap connected to the matching network via a first end and to the RF filter via a second end, a body with a body space to house the metal strap therein, and a connection member to connect the body to the RF filter.

14. The substrate processing apparatus of claim 13, wherein the body comprises at least one of metal and plastic.

15. The substrate processing apparatus of claim 13, further comprising a plurality of insulators to hold the metal strap in place within the body space, wherein the metal strap is spaced apart from the body within the body space.

16. The substrate processing apparatus of claim 13, wherein the connection member comprises a moving end member connected to the RF filter, a fixed end member connected to the body, and a bellows provided between the moving end member and the fixed end member.

17. The substrate processing apparatus of claim 16, wherein each of the moving end member, the fixed end member, and the bellows comprises a support member for supporting the metal strap within the bellows, wherein the metal strap is spaced apart from the bellows within a bellows space thereof.

18. The substrate processing apparatus of claim 17, wherein the support member comprises an insulator.

19. The substrate processing apparatus of claim 13, wherein the body comprises a first member connected to the matching network, a second member connected to the connection member, and a third member connecting the first member and the second member, wherein the first member is connected to the third member at a first predetermined angle and the second member is connected to the third member at a second predetermined angle.

20. The substrate processing apparatus of claim 13, further comprising an electromagnetic interference member configured to cover the metal strap to prevent an RF radiation leak therefrom.
